(19) United States
(12) Patent Application Publication
(10) Pub. No.: US 2025/0259928 A1
(43) Pub. Date: Aug. 14, 2025

(54) POWER SEMICONDUCTOR DEVICES

(71) Applicant: Samsung Electronics Co., Ltd., Suwon-si (KR)

(72) Inventors: Taehun KIM, Suwon-si (KR); Mingu KO, Suwon-si (KR); Youngcheol KIM, Suwon-si (KR); Jongseob KIM, Suwon-si (KR); Gyeongseon PARK, Suwon-si (KR); Younghwan PARK, Suwon-si (KR)

(73) Assignee: Samsung Electronics Co., Ltd., Suwon-si (KR)

(21) Appl. No.: 18/769,931

(22) Filed: Jul. 11, 2024

(30) Foreign Application Priority Data
Feb. 8, 2024 (KR) 10-2024-0019886

(51) Int. Cl. H01L 23/528; H01L 27/088; H01L 29/16; H01L 29/423; H01L 29/66; H01L 29/78

(52) U.S. Cl. CPC H01L 23/5283; H01L 23/5286; H10D 30/668; H10D 84/83; H10D 12/031; H10D 62/8325; H10D 64/513; H10D 64/516; H10D 64/518

(57) ABSTRACT

A power semiconductor device includes a substrate including SiC of a first conductivity type; a drift layer of the first conductivity type on the substrate; a well region of a second conductivity type on the drift layer; source regions of the first conductivity type on the well region; gate electrodes in gate trenches passing through the source regions and the well region and extending in a first direction parallel to an upper surface of the substrate; a gate pad electrically connected to the gate electrodes; a gate bus line connecting the gate pad and the gate electrodes, and including a region extending in a second direction intersecting the first direction; and a drain electrode on a lower surface of the substrate. At least one of the gate electrodes or the gate bus line has a cross-sectional area gradually changing in an extension direction.

### CROSS-REFERENCE TO RELATED APPLICATION(S)

This application claims benefit of priority to Korean Patent Application No. 10-2024-0019886 filed on Feb. 8, 2024 in the Korean Intellectual Property Office, the disclosure of which is incorporated herein by reference in its entirety.

### BACKGROUND

The present inventive concepts relate to power semiconductor devices.

Power semiconductor devices may be semiconductor devices that operate in high voltage and high current environments, and may be used in fields that require high power switching, such as power conversion, power converters, inverters, or the like. Power semiconductor devices basically require voltage resistance characteristics against high voltages, and recently, additionally require high-speed switching operations. Accordingly, power semiconductor devices using silicon carbide (SiC), which has superior voltage resistance characteristics, as compared to silicon (Si), are being researched.

### SUMMARY

Some example embodiments of the inventive concepts provide a power semiconductor device having improved electrical characteristics.

Some example embodiments of the inventive concepts provide a power semiconductor device that includes a substrate including SiC of a first conductivity type; a drift layer of the first conductivity type on the substrate; a well region of a second conductivity type on the drift layer; source regions of the first conductivity type on the well region; gate electrodes in gate trenches passing through the source regions and the well region, the gate electrodes extending in a first direction parallel to an upper surface of the substrate; a gate pad electrically connected to the gate electrodes; a gate bus line connecting the gate pad and the gate electrodes, the gate bus line including a first region extending from the gate pad in the first direction, and a second region extending from the first region in a second direction, the second region connected to end portions of the gate electrodes, and the second direction intersecting the first direction; and a drain electrode on a lower surface of the substrate. The second region has a first cross-sectional area in a first portion of the second region spaced from the gate pad by a first distance, and a second cross-sectional area greater than the first cross-sectional area of the second region in a second portion spaced from the gate pad by a second distance, the second distance being greater than the first distance.

Some example embodiments of the inventive concepts further provide a power semiconductor device that includes a substrate including SiC of a first conductivity type; a drift layer of the first conductivity type on the substrate; a well region of a second conductivity type on the drift layer; source regions of the first conductivity type on the well region; gate electrodes in gate trenches passing through the source regions and the well region, the gate electrodes extending in a first direction parallel to an upper surface of the substrate; a gate pad electrically connected to the gate electrodes; a gate bus line connecting the gate pad and the gate electrodes, the gate bus line including a region extending in a second direction, the second direction intersecting the first direction; and a drain electrode on a lower surface of the substrate. At least one of the gate electrodes or the gate bus line has cross-sectional area gradually changing in an extension direction.

Some example embodiments of the inventive concepts still further provides a power semiconductor device that includes a substrate including SiC of a first conductivity type; a drift layer of the first conductivity type on the substrate; a well region of a second conductivity type on the drift layer; source regions of the first conductivity type on the well region; gate electrodes extending in a first direction on the drift layer parallel to an upper surface of the substrate; a gate pad electrically connected to the gate electrodes; and a gate bus line connecting the gate pad and the gate electrodes, the gate bus line including a region extending in a second direction, the second direction intersecting the first direction. At least one of the gate electrodes or the gate bus line has a first cross-sectional area in a first portion having a first electrical path from the gate pad, and a second cross-sectional area greater than the first cross-sectional area in a second portion having a second electrical path, the second electrical path being longer than the first electrical path.

### BRIEF DESCRIPTION OF DRAWINGS

The above and other aspects, features, and advantages of the present inventive concepts will be more clearly understood from the following detailed description, taken in conjunction with the accompanying drawings, in which:

FIG. 1 is a schematic plan view of a power semiconductor device according to some example embodiments.

FIGS. 2A, 2B and 2C are schematic cross-sectional views of power semiconductor devices according to some example embodiments.

FIG. 3 is a cross-sectional view illustrating a power semiconductor device according to some example embodiments.

FIG. 4 is a plan view illustrating a power semiconductor device according to some example embodiments.

FIG. 5 is a plan view illustrating a power semiconductor device according to some example embodiments.

FIGS. 6A and 6B are plan views illustrating a power semiconductor device according to some example embodiments.

FIGS. 7A and 7B are schematic plan and cross-sectional views of a power semiconductor device according to some example embodiments.

FIG. 8 is a cross-sectional view illustrating a power semiconductor device according to some example embodiments.

FIGS. 9A, 9B, 9C, 9D, 9E and 9F are views illustrating a process sequence illustrating a method of manufacturing a power semiconductor device according to some example embodiments.

### DETAILED DESCRIPTION

Hereinafter, embodiments of the present inventive concepts will be described with reference to the accompanying drawings. Hereinafter, it can be understood that terms such as ‘on,’ ‘upper,’ ‘upper portion,’ ‘upper surface,’ ‘below,’ ‘lower,’ ‘lower portion,’ ‘lower surface,’ ‘side surface,’ and the like may be denoted by reference numerals and refer to the drawings, except where otherwise indicated.

When the terms “about” or “substantially” are used in this specification in connection with a numerical value, it is intended that the associated numerical value includes a manufacturing or operational tolerance (e.g., +10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes. When ranges are specified, the range includes all values therebetween such as increments of 0.1%.

Also, for example, “at least one of A, B, and C” and similar language (e.g., “at least one selected from the group consisting of A, B, and C”) may be construed as A only, B only, C only, or any combination of two or more of A, B, and C, such as, for instance, ABC, AB, BC, and AC.

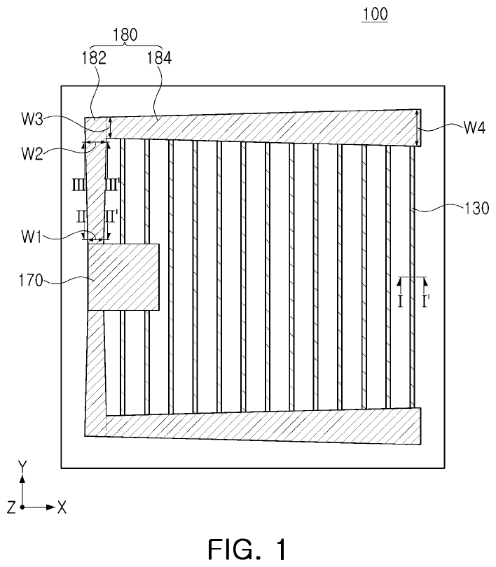

FIG. 1 is a schematic plan view of a power semiconductor device according to some example embodiments.

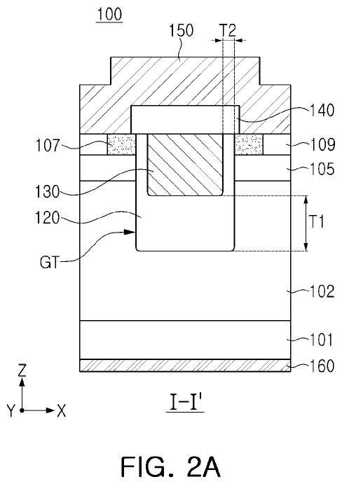

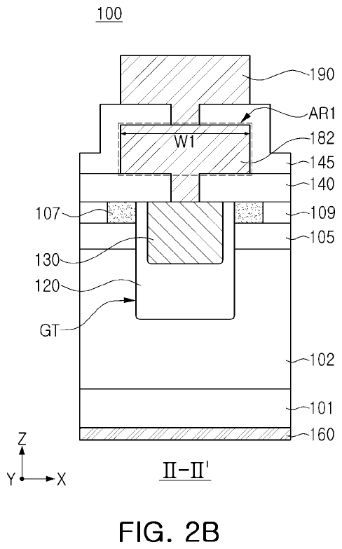

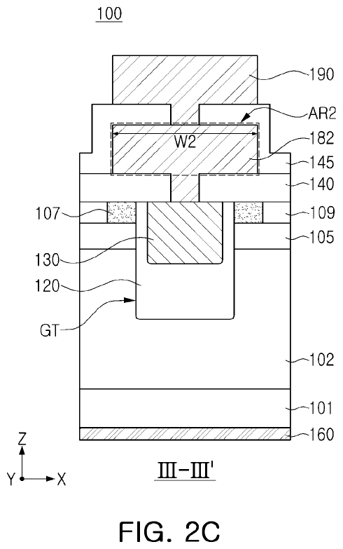

FIGS. 2A to 2C are schematic cross-sectional views of power semiconductor devices according to some example embodiments. FIG. 2A illustrates a cross-section of FIG. 1, taken along line I-I′, FIG. 2B illustrates a cross-section of FIG. 1, taken along line II-II′, and FIG. 2C illustrates a cross-section of FIG. 1, taken along line III-III′.

Referring to FIGS. 1 to 2C, a power semiconductor device 100 may include a substrate 101, a drift layer 102 on the substrate 101, well regions 105 on the drift layer 102, source regions 107 and well contact regions 109 on the well regions 105, gate insulating layers 120 disposed in gate trenches GT passing through the source regions 107 and the well regions 105, gate electrodes 130 disposed on the gate insulating layers 120 within the gate trenches GT, a gate pad 170 electrically connected to the gate electrodes 130, gate bus lines 180 connecting the gate electrodes 130 and the gate pad 170 and having a cross-sectional area changing in an extension direction, first dielectric layers 140 covering the gate electrodes 130, source electrode 150 on the first dielectric layers 140, second dielectric layers 145 covering the gate bus lines 180, a bus metal layer 190 on the gate bus lines 180, and a drain electrode 160 on a lower surface of the substrate 101.

The substrate 101 may have an upper surface extending in X- and Y-directions. The substrate 101 may include a semiconductor material, for example, SiC. In some example embodiments, the substrate 101 may include a group IV semiconductor material such as Si or Ge, or a compound semiconductor material such as SiGe, GaAs, InAs, or InP.

The substrate 101 may be provided as a bulk wafer or an epitaxial layer. The substrate 101 may include first conductivity-type impurities, and thus may have a first conductivity type. In some example embodiments, the first conductivity type may be an N-type, and the first conductivity-type impurities may be N-type impurities such as nitrogen (N) and/or phosphorus (P). In some example embodiments, the first conductivity type may be, for example, a P-type, and the first conductivity-type impurities may be, for example, P-type impurities such as aluminum (Al).

The drift layer 102 may be disposed on the substrate 101. The drift layer 102 may include a semiconductor material, and may include, for example, SiC. The drift layer 102 may be an epitaxial layer grown on the substrate 101. The drift layer 102 may include the first conductivity-type impurities, and thus may have the first conductivity type. A concentration of the first conductivity-type impurities in the drift layer 102 may be lower than a concentration of the first conductivity-type impurities in the substrate 101. In some example embodiments, the first conductivity-type impurities in the substrate 101 and the first conductivity-type impurities in the drift layer 102 may be the same as or different from each other.

The well regions 105 may be arranged at a desired (and/or alternatively predetermined) depth from an upper surface of the drift layer 102, and may be arranged to be spaced apart from each other by the gate trenches GT in a horizontal direction, for example, the X-direction. The well region 105 may include a semiconductor material, and may include, for example, SiC. The well region 105 may be a region having a second conductivity type, and may include second conductivity-type impurities. For example, the second conductivity type may be a P-type, and the second conductivity-type impurities may be P-type impurities such as aluminum (Al). In some example embodiments, the well region 105 may include a plurality of regions having different doping concentrations.

The source regions 107 may be disposed at a desired (and/or alternatively predetermined) depth from upper surfaces of the well regions 105. The source region 107 may include a semiconductor material, and may include, for example, SiC. The source region 107 may be a region having the first conductivity type, and may include the first conductivity-type impurities described above. A concentration of the first conductivity-type impurities in the source region 107 may be higher than a concentration of first conductivity-type impurities in the drift layer 102, but the present inventive concepts are not limited thereto.

The well contact regions 109 may be disposed on the well regions 105 on one side of at least a portion of the source regions 107. The well contact region 109 may be disposed between the well region 105 and the source electrode 150, to allow a voltage from the source electrode 150 to be applied to the well region 105. The well contact region 109 may include a semiconductor material, and may include, for example, SiC. The well contact region 109 may be a region having the second conductivity type, and may include the second conductivity-type impurities described above. A concentration of the second conductivity-type impurities in the well contact region 109 may be higher than a concentration of the second conductivity-type impurities in the well region 105.

The gate trenches GT may extend from upper surfaces of the source regions 107 through the source regions 107 and the well regions 105 into the drift layer 102. The gate trenches GT may be arranged to be spaced apart from each other in the X-direction. A portion of the gate trenches GT may extend below the gate bus lines 180. A portion of the gate trenches GT may extend below the gate pad 170. The gate trench GT may completely pass through the well region 105, and a lower end of the gate trench GT may be located within the drift layer 102.

However, a length of the gate trench GT extending into the drift layer 102 may be changed in some example embodiments. The gate insulating layer 120 and the gate electrode 130 may be disposed within the gate trench GT.

The gate insulating layers 120 may be respectively disposed within the gate trenches GT. The gate insulating layer 120 may extend along a bottom surface and side walls of the gate trench GT, and may cover side and lower surfaces of the gate electrode 130. The gate insulating layer 120 may be disposed between the source region 107 and the gate electrode 130, between the well region 105 and the gate electrode 130, and between the drift layer 102 and the gate electrode 130.

The gate insulating layer 120 may include an oxide, a nitride, or a high-k material. The high-K material may mean a dielectric material having a higher dielectric constant than a silicon dioxide (SiO₂). The high-K material may be, for example, any one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), or praseodymium oxide (Pr₂O₃).

The gate insulating layer 120 may have a non-uniform thickness. As illustrated in FIG. 2A, the gate insulating layer 120 may have a first thickness T1 on the bottom surface of the gate trench GT, and may have a second thickness T2, smaller than the first thickness T1 on the sidewalls of the gate trench GT. In some example embodiments, the gate insulating layer 120 may have a constant thickness.

The gate electrodes 130 may be respectively disposed within the gate trenches GT, may extend in the Y-direction, and may be spaced apart from each other in the X-direction. The gate electrode 130 may be disposed on the gate insulating layer 120 within the gate trench GT. The gate electrode 130 may overlap the drift layer 102, the well region 105, and the source region 107 in a horizontal direction, for example, the X-direction. A lower surface of the gate electrode 130 may be located within the drift layer 102 (e.g., may be located at a same level as the drift layer 102 along the Z-direction). In some example embodiments, the lower surface of the gate electrode 130 may be located within the well region 105 (e.g., may be located at a same level as the well region 105 along the Z-direction). The lower surface of the gate electrode 130 may be located on the same or lower level as a lower surface of the well region 105, and the upper surface of the gate electrode 130 may be located at the same or lower level as an upper surface of the source region 107. In some example embodiments, an upper surface of the gate electrode 130 may be located on a higher level than the upper surface of the source region 107. Some of the gate electrodes 130 may be arranged to overlap the gate pad 170 and the gate bus lines 180 in a Z-direction.

The gate electrode 130 may include a conductive material, and may include, for example, a semiconductor material such as doped polycrystalline silicon, or a metal material. The metal material may include, for example, at least one of titanium nitride (TiN), titanium (Ti), titanium carbide (TiC), tantalum nitride (TaN), tungsten nitride (WN), aluminum (Al), tungsten (W), or molybdenum (Mo). In some example embodiments, the gate electrode 130 may be provided as two or more layers.

The gate pad 170 and the gate bus lines 180 may be electrically connected to the gate electrodes 130, and may be a gate interconnection structure for connecting the gate electrodes 130 to the outside.

The gate pad 170 may be disposed on one side of the gate electrodes 130, and may be electrically connected to the gate electrodes 130 through gate bus lines 180. The gate pad 170 may be electrically connected to a separate pad metal layer disposed on the gate pad 170, and may receive an electrical signal through the pad metal layer. In some example embodiments, some of the gate electrodes 130 may extend below the gate pad 170, and may be connected perpendicularly to the gate pad 170. In some example embodiments, the gate pad 170 may have a rectangular shape, a circular shape, an elliptical shape, or the like, in plan view.

The gate bus lines 180 may be arranged in plural, for example two, and may be connected to one end portions and the other end portions of the gate electrodes 130, respectively. The gate bus lines 180 may be arranged symmetrically in the Y-direction based on the gate pad 170.

The gate bus line 180 may include first regions 182 and second regions 184. The first region 182 may be connected to the gate pad 170, and may be a region extending from the gate pad 170 in the Y-direction. The second region 184 may be a region extending from an end portion of the first region 182 in a direction, intersecting an extension direction of the gate electrodes 130, for example, in the X-direction. The gate bus line 180 may be disposed on at least one gate electrode 130, as illustrated in FIG. 2B. The gate bus line 180 may pass through a first dielectric layer 140 in at least one region, and may be vertically connected to the gate electrode 130 therebelow.

A cross-sectional area of each of the first region 182 and the second region 184 may respectively increase, as a distance of an electrical path from the gate pad 170 increases in the Y-direction and the X-direction. In this specification, unless otherwise specified, ‘cross-sectional area’ means an area of a cross-section, perpendicular to an extension direction. The cross-sectional area of each of the first region 182 and the second region 184 may increase as a distance from the gate pad 170 increases, for example, a width may increase. The width of each of the first region 182 and the second region 184 may gradually increase in an extension direction. In some example embodiments such as shown in FIG. 1, widths of the first region 182 and the second region 184 may increase continuously, and may increase linearly. In some example embodiments, the widths of the first region 182 and the second region 184 may increase discontinuously or non-linearly. The first region 182 and the second region 184 may have inclined side surfaces of which width increases as the distance from the gate pad 170 increases, in plan view.

The cross-sectional area of the first region 182 may increase away from the gate pad 170 in the Y-direction. The cross-sectional area of the second region 184 may increase, as the distance from the first region 182 increases. The first region 182 may have a first width W1 in a first portion spaced apart from the gate pad 170 by a first distance and a second width W2, greater than the first width W1, in a second portion spaced apart from the gate pad 170 by a second distance, greater than the first distance. The first region 182 may have a substantially constant thickness, and accordingly, may have a first cross-sectional area AR1 in the first portion, and a second cross-sectional area AR2, greater than the first cross-sectional area AR1, in the second portion. The second region 184 may have a third width W3 in a third portion spaced apart from the gate pad 170 by a third distance, and a fourth width W4, greater than the third width W3, in a fourth portion spaced apart from the gate pad 170 by a fourth distance, greater than the third distance. The second region 184 may have a substantially constant thickness, and accordingly, may have a third cross-sectional area in the third portion, and a fourth cross-sectional area, greater than the third cross-sectional area, in the fourth portion.

Relative sizes of the first width W1 and the second width W2, and relative sizes of the third width W3 and the fourth width W4 may be changed in some example embodiments.

The gate bus line 180 may have relatively high resistance in a region adjacent to the gate pad 170, for example, in the first portion and the third portion, and may have relatively low resistance in a region spaced apart from the gate pad 170, for example, in the second portion and the fourth portion, by shapes of the first region 182 and the second region 184, as described above. Therefore, in the power semiconductor device 100, a phenomenon in which a relatively large voltage drop occurs in a region far from the gate pad 170 may be alleviated, and uniformity of the voltage drop may be improved. Therefore, in the power semiconductor device 100, uniformity of the voltage applied to the gate electrodes 130 through the gate pad 170 may be improved.

The gate pad 170 and the gate bus lines 180 may include a conductive material, and may include, for example, a metal material. The gate pad 170 and the gate bus lines 180 may include the same or different materials from the gate electrode 130. The gate pad 170 and the gate bus lines 180 may include, for example, at least one of titanium nitride (TiN), titanium (Ti), titanium carbide (TiC), tantalum nitride (TaN), tungsten nitride (WN), aluminum (Al), tungsten (W), or molybdenum (Mo).

The first dielectric layers 140 may cover the gate electrodes 130, and may be disposed to expose a portion of each of the source regions 107 and a portion of each of the well contact regions 109. The first dielectric layer 140 may expose a portion of the gate electrode 130 below the gate bus line 180. The second dielectric layers 145 may cover the gate bus lines 180, and may expose a portion of the gate bus lines 180. In some example embodiments, the second dielectric layers 145 may also extend onto the source electrode 150.

A first dielectric layer 140 and a second dielectric layer 145 may each include an insulating material, and may include at least one of a silicon oxide, a silicon nitride, or a silicon oxynitride. In some example embodiments, at least one of the first dielectric layer 140 or the second dielectric layer 145 may include a high-k material.

The source electrode 150 may be disposed on the first dielectric layer 140, and may be electrically connected to the source regions 107 and the well contact regions 109. The source electrode 150 may be formed of a metal material, for example, at least one of nickel (Ni), aluminum (Al), titanium (Ti), silver (Ag), vanadium (V), tungsten (W), cobalt (Co), molybdenum (Mo), copper (Cu), or ruthenium (Ru). The source electrode 150 may include a metal-semiconductor compound layer disposed on an interface contacting the source regions 107 and the well contact regions 109. The metal-semiconductor compound layer may include a metal element and a semiconductor element, and may include, for example, at least one of TiSi, CoSi, MoSi, LaSi, NiSi, TaSi, or Wsi.

The bus metal layer 190 may be disposed on the gate bus lines 180 and the second dielectric layer 145, and may be connected to the gate bus lines 180 exposed from the second dielectric layer 145. The bus metal layer 190 may be arranged to have the same or similar shape as the gate bus lines 180, in plan view. In some example embodiments, the bus metal layer 190 may have a constant width, in plan view. A separate pad metal layer may be further disposed on the gate pad 170, and the pad metal layer may be, for example, a wire-bonded region within a package or a module. In some example embodiments, the bus metal layer 190 and the pad metal layer may be omitted.

The bus metal layer 190 may include a metal material, and may include, for example, at least one of copper (Cu), aluminum (Al), silver (Ag), nickel (Ni), titanium (Ti), vanadium (V), tungsten (W), cobalt (Co), molybdenum (Mo), or ruthenium (Ru).

The drain electrode 160 may be disposed on the lower surface of the substrate 101, and may be electrically connected to the substrate 101. The drain electrode 160 may include a metal material, for example, at least one of nickel (Ni), aluminum (Al), titanium (Ti), silver (Ag), vanadium (V), or tungsten (W). In some example embodiments, the drain electrode 160 may also include a metal-semiconductor compound layer, similar to the source electrode 150.

The power semiconductor device 100 has been illustrated as a metal oxide semiconductor field effect transistor (MOSFET), but shapes of the gate bus lines 180 in some example embodiments may also be applied to a super junction MOSFET, a double trench MOSFET, an insulated gate bipolar transistor (IGBT) device, or the like. For example, when the power semiconductor device is an IGBT, the substrate 101 may have the second conductivity type.

In the description of the following embodiments, descriptions overlapping those described above with reference to FIGS. 1 to 2C will be omitted.

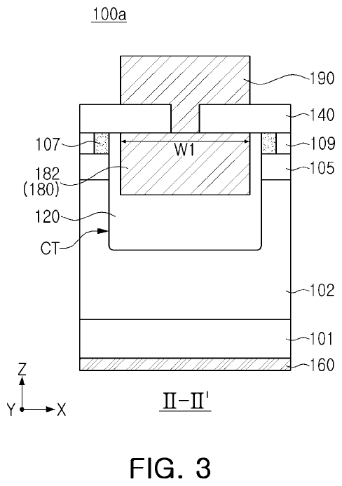

FIG. 3 is a cross-sectional view illustrating a power semiconductor device according to some example embodiments. FIG. 3 illustrates a region corresponding to FIG. 2B.

Referring to FIG. 3, in a power semiconductor device 100a, a gate bus line 180 may be disposed in a connection trench CT. The connection trench CT may extend from upper surfaces of source regions 107 through the source regions 107 and well regions 105 into a drift layer 102. The connection trench CT may be formed, together with the gate trenches GT of FIG. 2A, and may be located on the same level as the gate trenches GT.

A gate insulating layer 120 may be disposed in the connection trench CT, and the gate bus line 180 may be disposed on the gate insulating layer 120. The gate insulating layer 120 in the connection trench CT may be only a layer formed together with gate insulating layers 120 in the gate trenches GT, and may not actually function as a gate insulating layer of a transistor. Therefore, the gate insulation layer 120 in the connection trench CT may be referred to as a trench insulation layer. An upper surface of the gate bus line 180 may be located at substantially the same level as upper surfaces of the gate electrodes 130, the upper surfaces of the source regions 107, and an upper surface of the drift layer 102. Similarly, a gate pad 170 (see FIG. 1) may also be disposed within connection trench CT.

A first dielectric layer 140 may be disposed on the gate bus line 180. A bus metal layer 190 may be connected to the gate bus line 180 through the first dielectric layer 140.

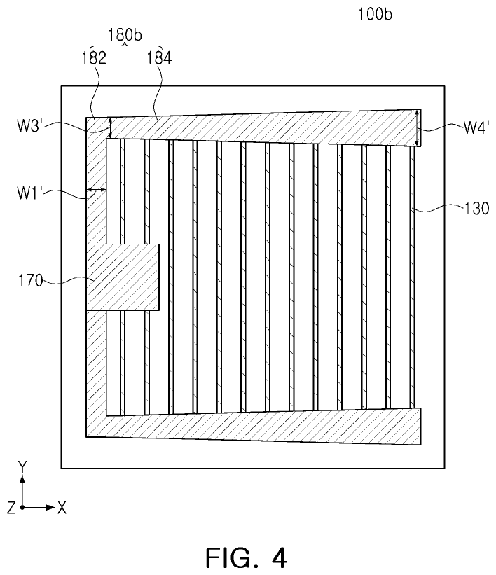

FIG. 4 is a plan view illustrating a power semiconductor device according to some example embodiments.

Referring to FIG. 4, in a power semiconductor device 100b, a shape of a first region 182 of a gate bus line 180b may be different from that in the embodiment of FIGS. 1 to 2C. The first region 182 may have a first width W1′ that may be substantially constant in the Y-direction. A second region 184 may have a shape of which a width increases away from a gate pad 170 in the X-direction. The second region 184 may have a third width W3′ in a portion spaced apart from the gate pad 170 by a relatively small distance, and may have a fourth width W4′, greater than the third width W3′, in a portion spaced apart from the gate pad 170 by a relatively long distance.

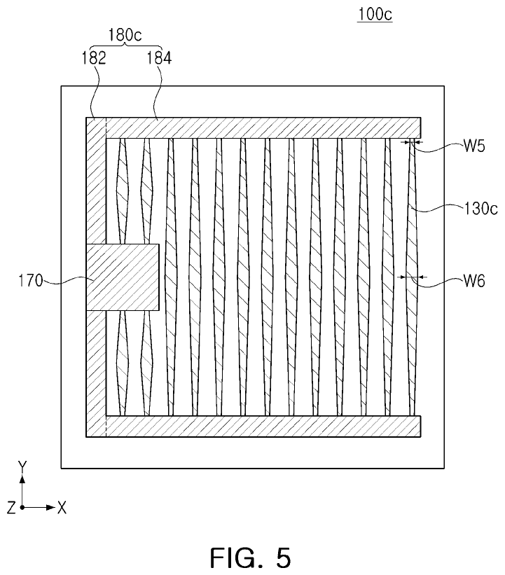

FIG. 5 is a plan view illustrating a power semiconductor device according to some example embodiments.

Referring to FIG. 5, in a power semiconductor device 100c, shapes of gate electrodes 130c and a gate bus line 180c may be different from those in the embodiment of FIGS. 1 to 2C. In some example embodiments, the gate bus line 180c may include first regions 182 and second regions 184, extending from a gate pad 170 at a constant width.

As the gate electrode 130c extends from a first end portion to a second end portion in the Y-direction, a cross-sectional area thereof may increase and then decrease again. A cross-sectional area and a width of the gate electrode 130c may gradually increase and then decrease in the Y-direction. In some example embodiments, a thickness of the gate electrode 130c may be substantially constant. The cross-sectional area and the width of the gate electrode 130c may be continuously changed in the Y-direction, and may be changed linearly. In some example embodiments, the cross-sectional area and width of the gate electrode 130c may be changed discontinuously or non-linearly.

The gate electrode 130c may have a fifth width W5 in portions adjacent to end portions connected to the second region 184 of the gate bus line 180c, and may have a sixth width W6, greater than the fifth width W5, in a central portion in the Y-direction. Relative sizes of the fifth width W5 and the sixth width W6 may be changed in some example embodiments. Some of the gate electrodes 130c may have a relatively small width in an end portion connected to the second region 184 of the gate bus line 180c and in an end portion connected to the gate pad 170, and may have a relatively large width in a central portion in the Y-direction. The gate electrode 130c may have a symmetrical shape with respect to a center in the Y-direction.

Due to this shape, the gate electrode 130c may have high resistance in a region in which an electrical path from the gate pad 170 is relatively short, for example, in an end portion connected to the second region 184, and may have low resistance in a region in which an electrical path from the gate pad 170 is relatively long, for example, in a center of the gate electrode 130c in the Y-direction. Therefore, in the power semiconductor device 100c, a phenomenon in which a relatively large voltage drop occurs in a region far from the gate pad 170 may be alleviated, and uniformity of a voltage drop may be improved.

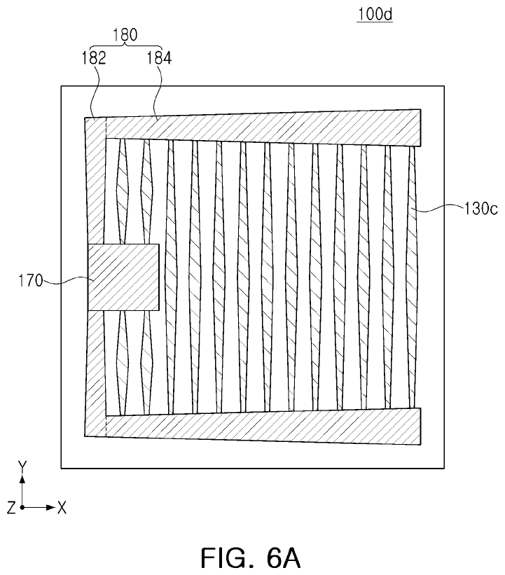

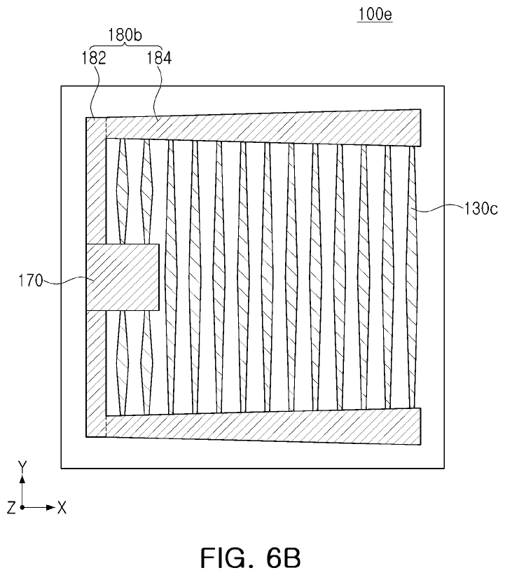

FIGS. 6A and 6B are plan views illustrating a power semiconductor device according to some example embodiments.

Referring to FIG. 6A, in a power semiconductor device 100d, a first region 182 and a second region 184 of respective gate bus lines 180 may have a shape of which a width increases away from a gate pad 170, and gate electrodes 130c may have a shape of which a width increases toward a center in the Y-direction. The description above with reference to FIGS. 1 to 2C may be equally applied to the gate bus lines 180, and the description above with reference to FIG. 5 may be equally applied to the gate electrodes 130c.

Referring to FIG. 6B, in a power semiconductor device 100e, a second region 184 of respective gate bus lines 180b may have a shape of which a width increases away from a gate pad 170 in the X-direction, and gate electrodes 130c may have a shape of which a width increases toward a center in the Y-direction. The description above with reference to FIG. 4, may be equally applied to the gate bus lines 180b, and the description, described above with reference to FIG. 5, may be equally applied to the gate electrodes 130c.

In some example embodiments, the shape of the gate electrodes 130c of FIG. 5 may also be applied to FIG. 3.

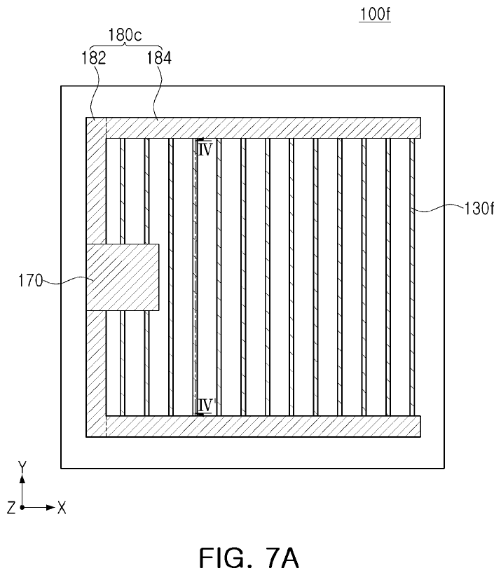

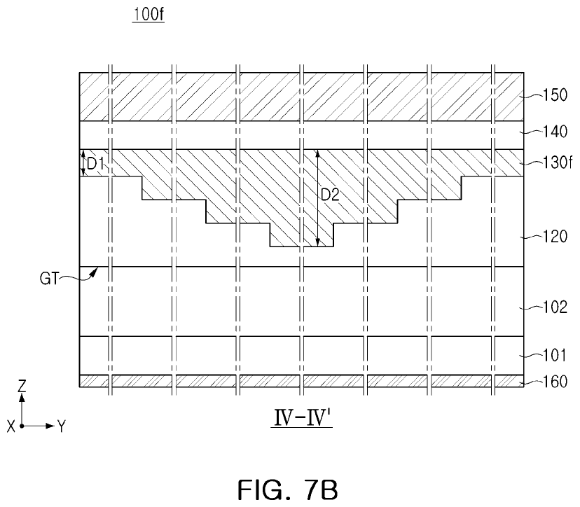

FIGS. 7A and 7B are schematic plan and cross-sectional views of a power semiconductor device according to some example embodiments. FIG. 7B illustrates a cross-section of FIG. 7A, taken along line IV-IV′.

Referring to FIGS. 7A and 7B, in a power semiconductor device 100f, shapes of gate electrodes 130f may be different from those in FIG. 5. As the gate electrode 130f extends from a first end portion to a second end portion in the Y-direction, a cross-sectional area may increase and then decrease again. A depth or a thickness of the gate electrode 130f in the Z-direction within a gate trench GT may gradually increase and then decrease. The depth of the gate electrode 130f in the Z-direction may be changed discontinuously, for example, in a stepped manner.

The gate electrode 130f has a first depth D1 from an upper surface in portions adjacent to end portions connected to a second region 184 of a gate bus line 180c, and may have a second depth D2, greater than the first depth D1, in a central portion in the Y-direction. The second depth D2 may be the maximum depth of the gate electrode 130f. Relative sizes of the first depth D1 and the second depth D2 and the number of steps of the gate electrode 130f may be changed in some example embodiments. At least some of the gate electrodes 130f may have a relatively small depth in an end portion connected to the second region 184 of the gate bus line 180c and in an end portion connected to a gate pad 170, and may have a relatively large depth in a central portion in the Y-direction. In some example embodiments, a width of the gate electrode 130f may be substantially constant. The gate electrode 130f may have a symmetrical shape with respect to a center in the Y-direction.

Due to this shape of the gate electrode 130f, as described above with reference to FIG. 5, a phenomenon in which a relatively large voltage drop occurs in a region far from the gate pad 170 may be alleviated, and uniformity of a voltage drop may be improved. This shape of the gate electrode 130f may also be applied to the embodiments of FIGS. 1 to 6B.

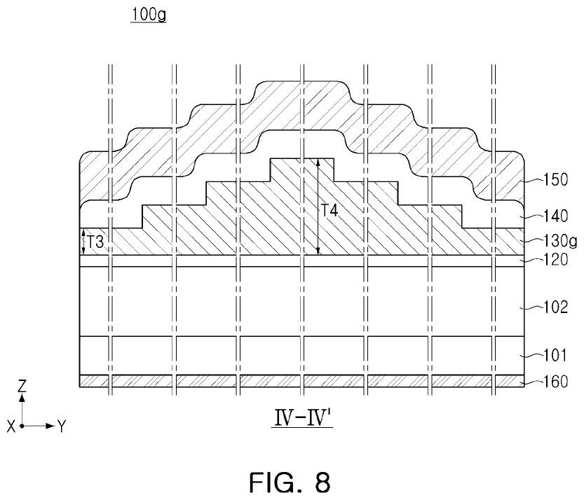

FIG. 8 is a cross-sectional view illustrating a power semiconductor device according to some example embodiments. FIG. 8 illustrates a region corresponding to FIG. 7B.

Referring to FIG. 8, in a power semiconductor device 100g, shapes of gate electrodes 130g may be different from those in the embodiment of FIG. 7B. In the present embodiment, the gate electrodes 130g may not be disposed within gate trenches GT extending into a drift layer 102 (see FIG. 7B), but may be disposed on the drift layer 102. Gate insulating layers 120 may be disposed on the drift layer 102 and below the gate electrodes 130g.

As a gate electrode 130g extends from a first end portion to a second end portion in the Y-direction, a cross-sectional area may increase and then decrease again. A thickness of the gate electrode 130g in the Z-direction may gradually increase and then decrease. The thickness of the gate electrode 130g in the Z-direction may be changed discontinuously, for example, in a stepped manner.

The gate electrode 130g has a third thickness T3 from an upper surface in portions adjacent to end portions connected to a second region 184 of a gate bus line 180c, and may have a fourth thickness T4, greater than the third thickness T3, in a central portion in the Y-direction. The fourth thickness T4 may be the maximum thickness of the gate electrode 130g. Relative sizes of the third thickness T3 and the fourth thickness T4 and the number of steps of the gate electrode 130g may be changed in some example embodiments. At least some of the gate electrodes 130g may have a relatively small thickness in an end portion connected to the second region 184 of the gate bus line 180c and in an end portion connected to a gate pad 170, and may have a relatively large thickness in a central portion in the Y-direction. In some example embodiments, a width of the gate electrode 130g may be substantially constant. The gate electrode 130g may have a symmetrical shape with respect to a center in the Y-direction. This shape of the gate electrode 130g may also be applied to the embodiments of FIGS. 1 to 6B.

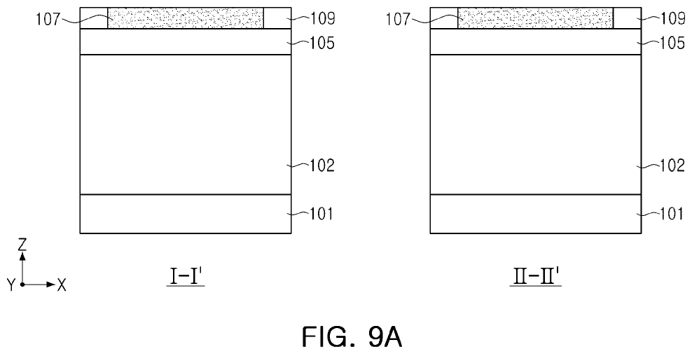

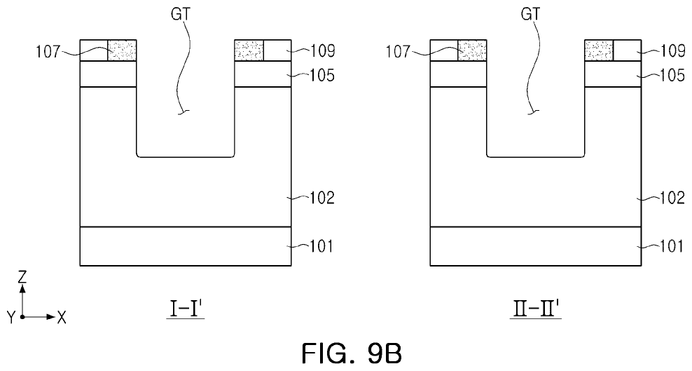

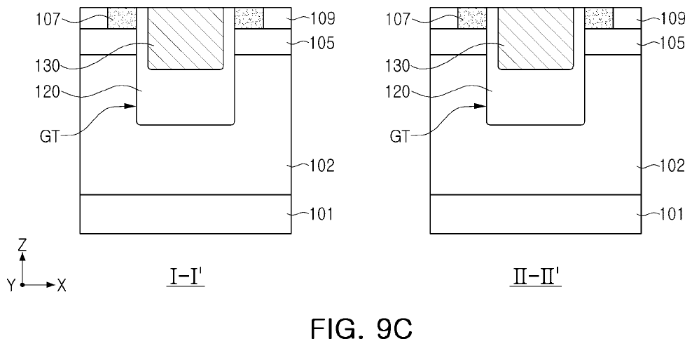

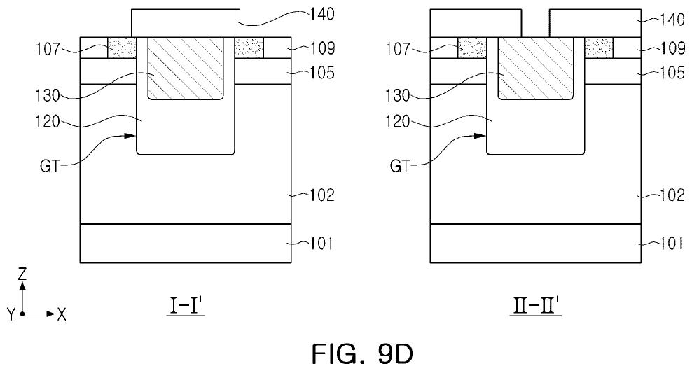

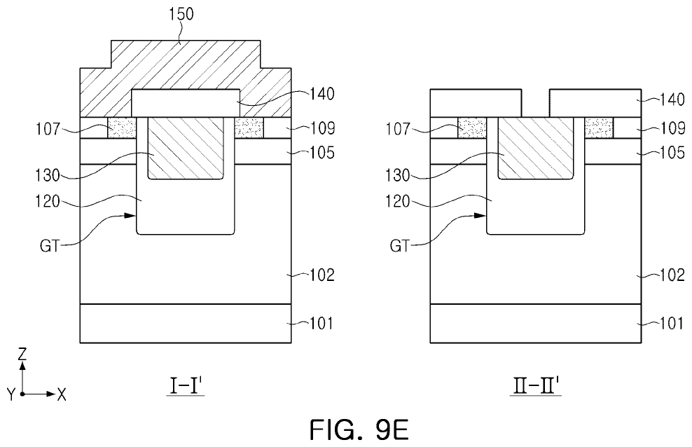

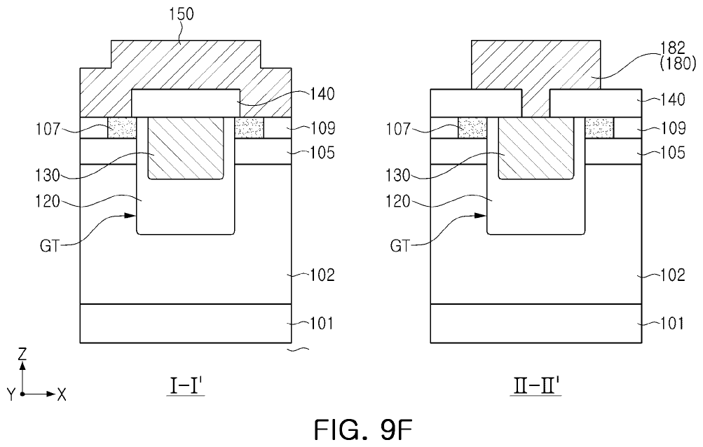

FIGS. 9A to 9F are views illustrating a process sequence illustrating a method of manufacturing a power semiconductor device according to some example embodiments. FIGS. 9A to 9F illustrate a method of manufacturing the power semiconductor device of FIGS. 1 to 2C, and also illustrate regions corresponding to FIGS. 2A and 2B, respectively.

Referring to FIG. 9A, a drift layer 102 may be formed on a substrate 101, and a well region 105, source regions 107, and well contact regions 109 may be formed.

The substrate 101 may be provided as a SiC wafer, for example. The drift layer 102 may be formed by epitaxial growth from the substrate 101. The drift layer 102 may be formed to include first conductivity-type impurities.

The well region 105, the source regions 107, and the well contact regions 109 may be sequentially formed in the drift layer 102 by an ion implantation process. Second conductivity-type impurities may be implanted into the well region 105 and the well contact regions 109, and first conductivity-type impurities may be implanted into the source regions 107. After the ion implantation process, an annealing process may be performed at a high temperature, for example, at a temperature of about 1600° C. to about 1800° C.

In some example embodiments, in a right region of FIG. 9A corresponding to FIG. 2B, at least one of the well region 105, the source region 107, or the well contact region 109 may not be formed. Alternatively, in some example embodiments, even in a region corresponding to FIG. 2B, at least one of the well region 105, the source region 107, or the well contact region 109 may be formed and subsequently removed.

Referring to FIG. 9B, gate trenches GT may be formed.

A gate trench GT may be formed by partially removing the source region 107, the well region 105, and the drift layer 102 using a separate mask layer. The drift layer 102 may be exposed through bottoms of the gate trench GT.

Referring to FIG. 9C, a gate insulating layer 120 and a gate electrode 130 may be formed.

The gate insulating layer 120 may be prepared by forming an insulating layer to fill the gate trench GT and then partially removing the insulating layer. Alternatively, the gate insulating layer 120 may be prepared by first forming a first insulating layer, which is uniform, by an oxidation process, for example, a thermal oxidation process, and may be prepared by further forming a second insulating layer on the first insulating layer using a spin-on glass (SOG) process or a high temperature oxide (HTO) process. The gate insulating layer 120 may be formed thicker on a bottom surface of the gate trench GT than on sidewalls of the gate trench GT. Next, a conductive material may be deposited to form the gate electrode 130 within the gate trench GT.

Referring to FIG. 9D, first dielectric layers 140 may be formed.

A first dielectric layer 140 may be entirely deposited on an upper surface of a structure being manufactured and then partially removed by an etching process to expose a portion of each of the source regions 107 and the well contact regions 109. In the right region of FIG. 9D corresponding to FIG. 2B, the first dielectric layer 140 may be formed to expose a portion of the gate electrode 130. In some example embodiments, a process of partially removing the first dielectric layer 140 to expose the portion of the gate electrode 130 may be performed in a subsequent operation.

Referring to FIG. 9E, a source electrode 150 may be formed on the first dielectric layer 140.

The source electrode 150 may be formed, for example, by entirely depositing a conductive material on an upper surface of a structure being manufactured and then removing a portion thereof by an etching process. In the right region of FIG. 9E corresponding to FIG. 2B, the source electrode 150 may be entirely removed.

Referring to FIG. 9F, a gate bus line 180 may be formed.

The gate bus line 180 may be formed on the first dielectric layer 140, and may be connected to the gate electrode 130 below through an open region of the first dielectric layer 140. At this operation, a gate pad 170 (see FIG. 1) may also be formed along with the gate bus line 180.

Next, referring to FIGS. 2A to 2C together, a second dielectric layer 145 may be formed on the gate bus line 180, and a bus metal layer 190 connected to the gate bus line 180 may be formed on the second dielectric layer 145, and a drain electrode 160 may be formed on a lower surface of the substrate 101. In some example embodiments, the drain electrode 160 may be formed in a different process. As a result, the power semiconductor device 100 of FIGS. 1 to 2C may be manufactured.

A shape of a gate bus line and/or a shape of a gate electrode in consideration of an electrical path from a gate pad may be optimized to provide a power semiconductor device having improved electrical characteristics.

Various advantages and effects of the present inventive concepts are not limited to the above-described content, and can be more easily understood through description of some example embodiments of the present inventive concepts.

While some example embodiments have been illustrated and described above, it will be apparent to those skilled in the art that modifications and variations could be made without departing from the scope of the present inventive concepts as defined by the appended claims.

What is claimed is:

1. A power semiconductor device comprising:
a substrate including SiC of a first conductivity type;
a drift layer of the first conductivity type on the substrate;
a well region of a second conductivity type on the drift layer;
source regions of the first conductivity type on the well region;
gate electrodes in gate trenches passing through the source regions and the well region, the gate electrodes extending in a first direction parallel to an upper surface of the substrate;
a gate pad electrically connected to the gate electrodes;
a gate bus line connecting the gate pad and the gate electrodes, the gate bus line including a first region extending from the gate pad in the first direction, and a second region extending from the first region in a second direction, the second region connected to end portions of the gate electrodes, and the second direction intersecting the first direction; and
a drain electrode on a lower surface of the substrate,
wherein the second region has a first cross-sectional area in a first portion of the second region spaced from the gate pad by a first distance, and a second cross-sectional area greater than the first cross-sectional area of the second region in a second portion spaced from the gate pad by a second distance, the second distance being greater than the first distance.

2. The power semiconductor device of claim 1, wherein the second region has a first width in the first portion, and a second width greater than the first width in the second portion.

3. The power semiconductor device of claim 1, wherein the second region has a width gradually increasing away from the first region.

4. The power semiconductor device of claim 1, wherein the first region has a first width in a portion of the first region spaced apart from the gate pad by a third distance, and a second width greater than the first width in a portion of the first region spaced apart from the gate pad by a fourth distance, the fourth distance being greater than the third distance.

5. The power semiconductor device of claim 4, wherein the first region has a width gradually increasing away from the gate pad.

6. The power semiconductor device of claim 1, wherein the gate bus line is on at least one gate electrode among the gate electrodes, and is vertically connected to the at least one gate electrode.

7. The power semiconductor device of claim 1, wherein the gate bus line is in a connection trench extending into the drift layer.

8. The power semiconductor device of claim 1, wherein at least one gate electrode from among the gate electrodes has a third cross-sectional area in a portion of the at least one gate electrode spaced apart from the gate bus line by a third distance, and has a fourth cross-sectional area greater than the third cross-sectional area in a portion of the at least one gate electrode spaced apart from the gate bus line by a fourth distance, the fourth distance being greater than the third distance.

9. The power semiconductor device of claim 8, wherein the at least one gate electrode has a width that gradually increases and then decreases in the first direction.

10. The power semiconductor device of claim 1, further comprising gate insulating layers below the gate electrodes within the gate trenches,
wherein each of the gate insulating layers has a first thickness on a bottom surface of each of the gate trenches, and a second thickness less than the first thickness on a sidewall of each of the gate trenches.

11. The power semiconductor device of claim 1, further comprising:
a dielectric layer on the gate electrodes; and
a source electrode connected to the source regions on the dielectric layer.

12. The power semiconductor device of claim 1, wherein the drift layer and the well region include SiC.

13. A power semiconductor device comprising:
a substrate including SiC of a first conductivity type;
a drift layer of the first conductivity type on the substrate;
a well region of a second conductivity type on the drift layer;
source regions of the first conductivity type on the well region;
gate electrodes in gate trenches passing through the source regions and the well region, the gate electrodes extending in a first direction parallel to an upper surface of the substrate;
a gate pad electrically connected to the gate electrodes;
a gate bus line connecting the gate pad and the gate electrodes, the gate bus line including a region extending in a second direction, the second direction intersecting the first direction; and
a drain electrode on a lower surface of the substrate,
wherein at least one of the gate electrodes or the gate bus line has cross-sectional area gradually changing in an extension direction.

14. The power semiconductor device of claim 13, wherein the gate bus line has a first cross-sectional area in a portion of the gate bus line spaced apart from the gate pad by a first distance, and a second cross-sectional area greater than the first cross-sectional area in a portion of the gate bus line spaced from the gate pad by a second distance, the second distance being greater than the first distance.

15. The power semiconductor device of claim 13, wherein the gate bus line comprises, in plan view, a region having inclined side surfaces such that a width of the gate bus line increases in the extension direction.

16. The power semiconductor device of claim 13, wherein the gate electrodes have a first cross-sectional area in a portion of the gate electrodes spaced apart from the gate bus line by a first distance, and a second cross-sectional area greater than the first cross-sectional area in a portion of the gate electrodes spaced apart from the gate bus line by a second distance, the second distance being greater than the first distance.

17. The power semiconductor device of claim 13, wherein the gate electrodes have a shape symmetric with respect to a center of the gate electrodes in the first direction.

18. A power semiconductor device comprising:
a substrate including SiC of a first conductivity type;
a drift layer of the first conductivity type on the substrate;
a well region of a second conductivity type on the drift layer;
source regions of the first conductivity type on the well region;
gate electrodes extending in a first direction on the drift layer parallel to an upper surface of the substrate;
a gate pad electrically connected to the gate electrodes; and
a gate bus line connecting the gate pad and the gate electrodes, the gate bus line including a region extending in a second direction, the second direction intersecting the first direction,
wherein at least one of the gate electrodes or the gate bus line has a first cross-sectional area in a first portion having a first electrical path from the gate pad, and a second cross-sectional area greater than the first cross-sectional area in a second portion having a second electrical path, the second electrical path being longer than the first electrical path.

19. The power semiconductor device of claim 18, wherein the at least one of the gate electrodes or the gate bus line has a first resistance in the first portion, and a second resistance less than the first resistance in the second portion.

20. The power semiconductor device of claim 18, wherein the gate electrodes have a first thickness in the first portion, and a second thickness greater than the first thickness in the second portion.
